(19) United States
(12) Patent Application Publication
(10) Pub. No.: US 2017/0370018 A1
(43) Pub. Date: Dec. 28, 2017

(54) METHOD FOR PRODUCING CRYSTAL

(71) Applicant: Kyocera Corporation, Kyoto-shi, Kyoto (JP)

(72) Inventors: Chiaki DOMOTO, Soraku-gun (JP); Katsuaki MASAKI, Kyoto-shi (JP); Yutaka KUBA, Soraku-gun (JP)

(21) Appl. No.: 15/546,413

(22) PCT Filed: Jan. 19, 2016
(86) PCT No.: PCT/JP2016/051449

§ 371 Date: Jul. 26, 2017

(30) Foreign Application Priority Data
Jan. 29, 2015 (JP) 2015-015421

(51) Int. Cl. C30B 15/14; C30B 29/36; C30B 15/20

(52) U.S. Cl. CPC C30B 15/14; C30B 15/20; C30B 29/36

(57) ABSTRACT

The method of the disclosure for producing a crystal is a method for producing a crystal of silicon carbide and includes a preparation step, a contact step, a first growth step, a heating step, a cooling step, and a second growth step. The preparation step includes preparing a seed crystal, a crucible, and a solution. The contact step includes bringing the seed crystal into contact with the solution. The first growth step includes heating the solution to a temperature in a first temperature range and pulling up the seed crystal with the temperature of the solution kept in the first temperature range to grow a crystal from the lower surface of the seed crystal. The heating step includes heating the solution. The cooling step includes cooling the solution. The second growth step includes further growing the crystal with the temperature of the solution kept in the first temperature range.

### TECHNICAL FIELD

The present invention relates to a method for producing a crystal of silicon carbide.

### BACKGROUND ART

Silicon carbide (SiC) that is a compound of carbon and silicon attracts attention as a material of the substrate on or in which transistors and other devices are formed. This is because, for example, silicon carbide has a wider band gap than silicon and, accordingly, the electric intensity at which an electrical breakdown occurs is high. For example, Japanese Unexamined Patent Application Publication No. 2012-136391 describes a method for producing silicon carbide crystal wafer and, further, an ingot of silicon carbide crystals.

### SUMMARY OF INVENTION

The method for producing a crystal disclosed herein, which is a method for producing a crystal of silicon carbide, includes a preparation step, a contact step, a first growth step, a heating step, a cooling step, and a second growth step. The preparation step includes a step of preparing a seed crystal, a crucible, and a solution in which carbon is dissolved in a silicon solvent in the crucible. The contact step includes a step of bringing the lower surface of the seed crystal into contact with the solution. The first growth step includes a step of heating the solution to a temperature in a first temperature range and pulling up the seed crystal with the temperature of the solution kept in the first temperature range to grow a crystal from the lower surface of the seed crystal. The heating step includes a step of heating the solution after the first growth step. The cooling step includes a step of cooling the solution after the first growth step. The second growth step includes a step of further growing the crystal with the temperature of the solution kept in the first temperature range after the heating step and the cooling step.

### BRIEF DESCRIPTION OF DRAWINGS

FIG. 1 is a schematic sectional view of an exemplary crystal producing apparatus used in the crystal producing method of the present disclosure.

FIG. 2 is a graph illustrating the general relationship between the elapsed time and the solution temperature in the crystal producing method of the present disclosure.

FIG. 3 is a graph illustrating the general relationship between the elapsed time and the solution temperature in the crystal producing method of the present disclosure.

FIG. 4 is a graph illustrating the general relationship between the elapsed time and the solution temperature in the crystal producing method of the present disclosure.

### DESCRIPTION OF EMBODIMENTS

<Crystal Producing Apparatus>

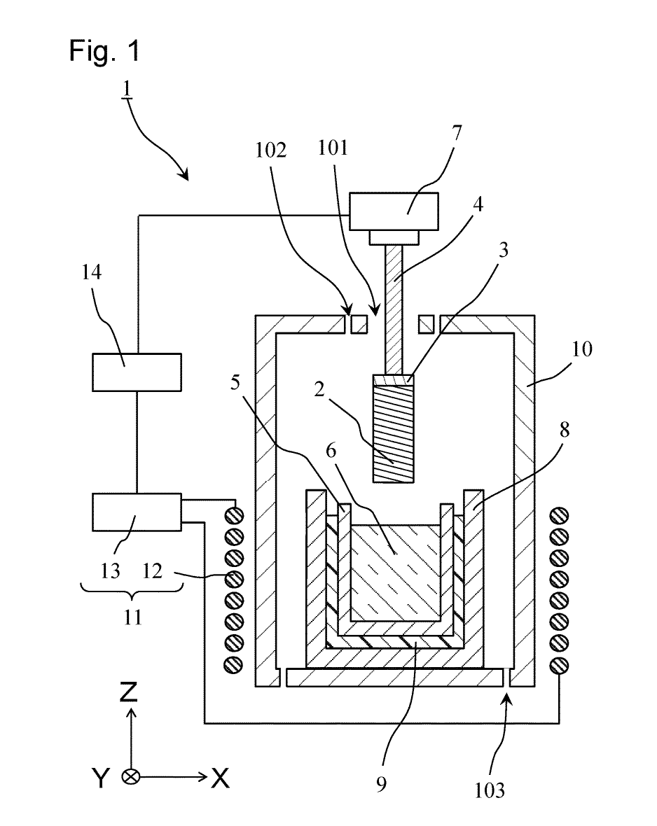

An exemplary crystal producing apparatus used in the crystal producing method of the present disclosure will now be described with reference to FIG. 1. FIG. 1 schematically illustrates a crystal producing apparatus. The subject matter is not limited to the embodiment disclosed herein (present embodiment), and various modifications and improvements may be made without departing from the spirit and scope of the invention.

A crystal producing apparatus 1 is intended to produce a crystal 2 of silicon carbide used in semiconductor components or the like. The crystal producing apparatus 1 allows a crystal 2 to grow from the lower surface of a seed crystal 3, thus producing the crystal 2. As illustrated in FIG. 1, the crystal producing apparatus 1 mainly includes a holding member 4 and a crucible 5. The seed crystal 3 is fixed to the holding member 4, and the crucible 5 contains a solution 6. The crystal producing apparatus 1 brings the lower surface of the seed crystal 3 into contact with the solution 6 and thus grows the crystal 2 from the lower surface of the seed crystal 3.

The crystal 2 may be, for example, processed into wafer that will be further processed into a part of a semiconductor component through a manufacturing process of the semiconductor component. The crystal 2 is a lump or mass of silicon carbide crystals grown from the lower surface of the seed crystal 3. The crystal 2 may be, for example, plate-like or columnar, having a circular or a polygonal cross section in plan view. The crystal 2 may be a monocrystalline silicon carbide crystal. The crystal 2 may have a diameter or a width in the range of, for example, 25 mm to 200 mm. The height of the crystal 2 may be in the range of, for example, 30 mm to 300 mm. The phrase “a diameter or a width” refers to the length of a straight line passing through the center in plan view of the crystal 2 and reaching the ends in plan view of the crystal. The height of the crystal 2 refers to the distance from the lower surface of the crystal 2 to the upper surface thereof (lower surface of the seed crystal 3).

The seed crystal 3 can act as the seed for growing the crystal 2 in the crystal producing apparatus 1. In other words, the seed crystal 3 is a foundation from which the crystal 2 grows. The seed crystal 3 may have a plate-like shape that is circular or polygonal in plan view. The seed crystal 3 may be a crystal of the same material as the crystal 2. Since a crystal 2 of silicon carbide is produced in the present embodiment, the seed crystal 3 is a silicon carbide crystal. The seed crystal 3 is monocrystalline or polycrystalline. In the present embodiment, the seed crystal 3 is monocrystalline.

The seed crystal 3 is fixed to the lower surface of the holding member 4. The seed crystal 3 may be fixed to the holding member 4 with, for example, an adhesive containing carbon.

The holding member 4 can hold the seed crystal 3. Also, the holding member 4 carries the seed crystal 3 into and out of the solution 6. In other words, the holding member 4 can bring the seed crystal 3 into contact with the solution 6 and move the crystal 2 off the solution 6.

The holding member 4 is fixed to a moving mechanism of a moving device 7, as illustrated in FIG. 1. The moving device 7 vertically moves the holding member 4 by using, for example, a motor. Consequently, the seed crystal 3 is vertically moved with the vertical movement of the holding member 4 caused by the moving device 7.

The holding member 4 may be, for example, columnar. The holding member 4 may be made of, for example, polycrystalline carbon or fired carbon. The holding member 4 may be fixed to the moving device 7 and rotatable on an axis extending in a vertical direction through the center in plan view of the holding member 4. In other words, the holding member 4 may rotate on its own axis.

The solution 6, which is accommodated (contained) in the crucible 5, supplies the raw material of the crystal 2 to the seed crystal 3, thus enabling the crystal 2 to grow. The solution 6 contains the same constituents as the crystal 2. More specifically, since the crystal 2 is a silicon carbide crystal, the solution 6 contains carbon and silicon. The solution 6 in the present embodiment is prepared by dissolving carbon as a solute in a solvent of silicon (silicon solvent). From the viewpoint of increasing the solubility of carbon and other reasons, the solution 6 may contain one or more metals, such as neodymium (Nd), aluminum (Al), tantalum (Ta), scandium (Sc), chromium (Cr), zirconium (Zr), nickel (Ni), or yttrium (Y), as an additive.

The crucible 5 can accommodate the solution 6. The crucible 5 allows the raw material of the crystal 2 to be melted therein. The crucible 5 may be made of, for example, a material containing carbon. The crucible 5 used in the present embodiment is made of, for example, graphite. In the present embodiment, silicon is melted within the crucible 5, and a part (carbon) of the crucible 5 is dissolved in the melted silicon to yield the solution 6. The crucible 5 is a member, for example, in a recessed shape whose top is open to receive the solution 6.

In the present embodiment, the crystal 2 of silicon carbide is grown by a solution method. In the solution method, while the solution 6 is kept in a thermodynamically metastable state near the seed crystal 3, the crystal 2 is grown from the lower surface of the seed crystal 3 under the condition controlled so that the crystal 2 is precipitated at a higher rate than the rate at which it is dissolved. In the solution 6, carbon (solute) is dissolved in silicon (solvent). The higher the temperature of the solvent, the higher the solubility of carbon. If the solution 6 heated to a high temperature is cooled by contact with the seed crystal 3, the dissolved carbon precipitates, and the solution 6 is supersaturated with the carbon, thus coming into a metastable state locally in the vicinity of the seed crystal 3. Then, the crystal 2 precipitates at the lower surface of the seed crystal 3 with the solution 6 coming into a stable state (thermodynamically equilibrium state). Consequently, the crystal 2 is grown from the lower surface of the seed crystal 3.

The crucible 5 is disposed within a crucible container 8. The crucible container 8 can hold the crucible 5. A heat insulation material 9 is disposed between the crucible container 8 and the crucible 5. The crucible 5 is surrounded by the heat insulation material 9. The heat insulation material 9 suppresses heat dissipation from the crucible 5 and helps the inside of the crucible 5 have a nearly uniform temperature distribution. The crucible 5 may be disposed within the crucible container 8 and rotatable on an axis extending in a vertical direction through the center of the bottom in plan view of the crucible 5. In other words, the crucible 5 may rotate on its own axis.

The crucible container 8 is disposed within a chamber 10. The chamber 10 can separate the space for growing the crystal 2 from the external atmosphere. The presence of the chamber 10 can reduce the contamination of the crystal 2 with unnecessary impurities. The chamber 10 may be filled with, for example, an inert gas. Thus, the inside of the chamber 10 can be isolated from the outside. The crucible container 8 may be supported by the bottom of the chamber 10, or may be supported by a support shaft extending downward from the lower surface of the crucible container 8 through the bottom of the chamber 10.

The chamber 10 has a through hole 101 through which the holding member 4 passes, a gas supply port 102 through which a gas is introduced into the chamber 10, and an exhaust port 103 through which the gas is discharged from the chamber 10. Furthermore, the crystal producing apparatus 1 includes a gas supply portion capable of supplying a gas into the chamber 10. The gas of the atmosphere in the crystal producing apparatus 1 is introduced into the chamber 10 through the supply port 102 from the gas supply portion and is discharged through the exhaust port 103.

The chamber 10 may be, for example, in a hollow cylindrical shape. The chamber 10 has a circular bottom with a diameter, for example, in the range of 150 mm to 1000 mm, and the height of the chamber is, for example, in the range of 500 mm to 2000 mm. The chamber 10 may be made of, for example, stainless steel or an insulating material, such as quartz. The inert gas introduced into the chamber 10 may be argon (Ar), helium (He), or the like.

The crucible 5 is heated with a heating device 11. The heating device 11 used in the present embodiment includes a coil 12 and an alternating-current power supply 13 and can heat the crucible 5 by, for example, electromagnetic heating using electromagnetic waves. The heating device 11 may operate, for example, to conduct heat generated from a heating resistor of carbon or the like or may operate in any other manner. If the heating device operates to conduct heat, a heating resistor is disposed (between the crucible 5 and the heat insulation material 9).

The coil 12 is made of a conductor and surrounds the periphery of the crucible 5. More specifically, the coil 12 is disposed around the chamber 10 in such a manner that the coil 12 cylindrically surrounds the crucible 5. The heating device 11 including the coil 12 has a hollow cylindrical heating region defined by the coil 12. Although the coil 12 is disposed around the chamber 10 in the present embodiment, the coil 12 may be disposed within the chamber 10.

The alternating-current power supply 13 can apply an alternating current to the coil 12. An electric field is generated by applying the current to the coil 12, and thus an induced current is generated at the crucible container 8 in the electric field. The Joule heat of the induced current heats the crucible container 8. The heat of the crucible container 8 is conducted to the crucible 5 through the heat insulation material 9, thus heating the crucible 5. The alternating current may be adjusted to a frequency at which the induced current flows easily to the crucible container 8. This can reduce the heating time for heating the inside of the crucible 5 to a predetermined temperature and increase power efficiency.

In the present embodiment, the alternating-current power supply 13 and the moving device 7 are connected to and controlled by a controller 14. Hence, the controller 14 controls the heating and temperature of the solution 6 and the carrying in and out of the seed crystal 3 in conjugation with each other in the crystal producing apparatus 1. The controller 14 includes a central processing unit and a storage device, such as a memory device, and is, for example, a known computer.

<Method for Producing Crystal>

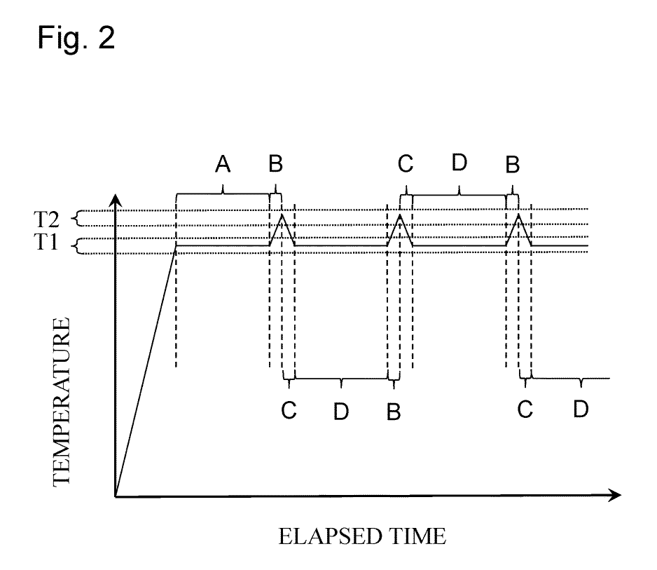

The method of the present disclosure for producing a crystal will now be described with reference to FIG. 2. FIG. 2 is an illustrative representation of the method of the present disclosure for producing a crystal and, more specifically, illustrates temperature changes of the solution 6 during the production of the crystal by means of a schematic graph with a horizontal axis representing elapsed time and a vertical axis representing temperature.

The crystal producing method mainly includes a preparation step, a first growth step, a heating step, a cooling step, a second growth step, and a removing step. The subject matter is not limited to the embodiment disclosed herein, and various modifications and improvements may be made without departing from the spirit and scope of the invention.

(Preparation Step)

A seed crystal 3 is prepared. The seed crystal 3 may be in a plate-like shape formed from a mass of silicon carbide crystals produced by, for example, sublimation or a solution method. In the present embodiment, a crystal 2 produced by the crystal producing method disclosed herein is used as the seed crystal 3. This enables the composition of the crystal 2 grown from the surface of the seed crystal 3 to have a composition similar to the composition of the seed crystal 3, and thus the occurrence of transition of the crystal 2 resulting from the difference in composition may be reduced. The plate-like shape can be formed by cutting a lump or mass of silicon carbide by machining.

A holding member 4 is prepared, and the seed crystal 3 is fixed to the lower surface of the holding member 4. More specifically, after preparing the holding member 4, an adhesive containing carbon is applied to the lower surface of the holding member 4. Subsequently, the seed crystal 3 is placed on the lower surface of the holding member 4 with the adhesive in between, and thus fixed to the lower surface of the holding member 4. In the present embodiment, after fixing the seed crystal 3 to the holding member 4, the upper end of the holding member 4 is fixed to the moving device 7. As described above, the holding member 4 is fixed to the moving device 7 and rotatable on the axis extending in a vertical direction through the center of the holding member 4.

A crucible 5 and a solution 6 of carbon dissolved in a silicon solvent in the crucible 5 are prepared. More specifically, the crucible 5 is first prepared. Then, silicon particles, or raw material of silicon, are placed in the crucible 5, and the crucible 5 is heated to the melting point of silicon (1420° C.) or higher. The carbon (solute) of the crucible 5 is dissolved in the melted liquid silicon (solvent). Consequently, the solution 6 of carbon dissolved in the silicon solvent is prepared in the crucible 5. Alternatively, the solution 6 containing carbon may be prepared by adding carbon particles to silicon particles in advance and dissolving the carbon particles simultaneously with melting the silicon particles.

The crucible 5 is placed in the chamber 10. In the present embodiment, the crucible 5 is disposed within the crucible container 8 with a heat insulation material 9 in between, in the chamber 10 surrounded by the coil 12 of the heating device 11. The solution 6 may be prepared by placing the crucible 5 in the chamber 10 and then heating the crucible 5 with the heating device 11. Alternatively, the solution 6 may be prepared by heating the crucible 5 outside the crystal producing apparatus 1 before the crucible 5 is placed within the chamber 10. The solution 6 may be prepared in a container other than the crucible 5, and then, poured into the crucible 5 within the chamber 10.

(Contact Step)

The lower surface of the seed crystal 3 is brought into contact with the solution 6. The holding member 4 is moved downward, and thus the lower surface of the seed crystal 3 is brought into contact with the solution 6. While the seed crystal 3 is brought into contact with the solution 6 by moving the seed crystal 3 downward in the present embodiment, the crucible 5 may be moved upward to bring the lower surface of the seed crystal 3 into contact with the solution 6.

At least the lower surface of the seed crystal 3 is in contact with the surface of the solution 6. The seed crystal 3 may be immersed in the solution 6 and the sides and the upper surface of the seed crystal 3, in addition to the lower surface, may come into contact with the solution 6.

(First Growth Step)

The crystal 2 is precipitated from the solution 6 and grown from the lower surface of the seed crystal 3 in contact with the solution 6. When the crystal 2 is grown, first, a difference in temperature occurs between the lower surface of the seed crystal 3 and the solution 6 in the vicinity of the lower surface of the seed crystal 3. If the difference in temperature between the seed crystal 3 and the solution 6 causes the carbon dissolved in the solution 6 to supersaturate the solution 6, the carbon and the silicon in the solution 6 precipitate as the crystal 2 of silicon carbide on the lower surface of the seed crystal 3, and the crystal 2 is grown. The crystal 2 is grown at least from the lower surface of the seed crystal 3, and may be grown from the lower surface and the side surfaces of the seed crystal 3.

The crystal 2 can be grown in a columnar shape by pulling up the seed crystal 3. More specifically, the crystal 2 can be grown with the width or the diameter of the crystal 2 kept at a predetermined value by gradually pulling the seed crystal 3 upward while adjusting the growth rate in the horizontal direction and downward direction of the crystal 2. The seed crystal 3 may be pulled at a rate, for example, in the range of 50 μm/h to 2000 μm/h.

The seed crystal 3 is pulled up with the solution 6 kept at a temperature in a first temperature range T1 after the solution 6 is heated to the temperature in the first temperature range, as illustrated in FIG. 2. Thus, the crystal 2 is grown while the solution 6 is controlled to a constant temperature. This control of the solution 6 to a constant temperature for growing the crystal 2 is easier than, for example, temperature control when the temperature of the solution 6 is varied, and leads to an increased work efficiency.

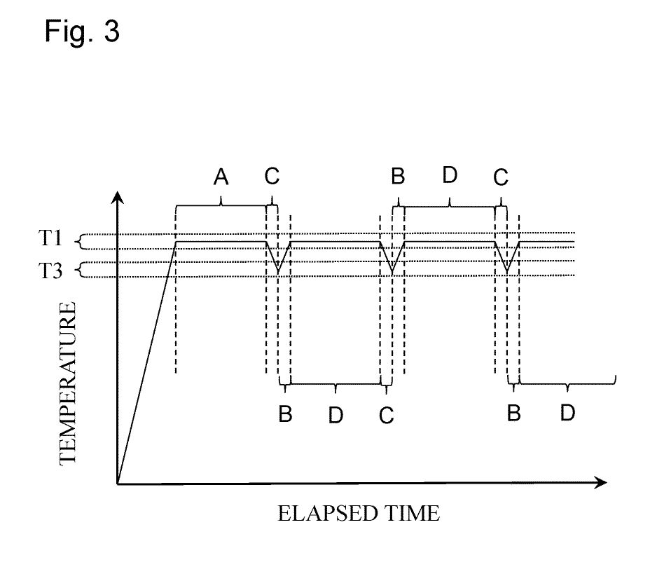

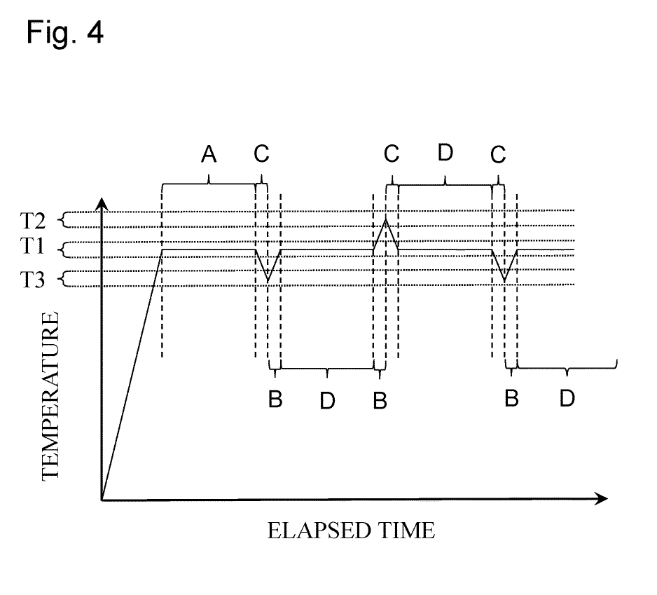

In FIG. 2, the first growth step is denoted by “A”; the heating step is denoted by “B”; the cooling step is denoted by “C”; and the second growth step is denoted by “D”. Similarly to FIG. 1, FIGS. 3 and 4 denote these steps by alphabets.

The first temperature range T1 refers to a range of temperatures within +10° C. from the temperature of the solution 6 while the crystal 2 is grown. The temperature of the solution 6 at which the crystal 2 is grown in the first growth step may be, for example, in the range of 1900° C. to 2100° C. The time period for growing the crystal 2 in the first growth step may be, for example, in the range of 10 hours to 150 hours.

The temperature of the solution 6 may be directly measured with, for example, a thermocouple or may be indirectly measured with a radiation thermometer. If the temperature of the solution 6 varies, the temperature may be measured a plurality of times in a specific period, and the average of the measured temperatures may be used as the temperature of the solution 6.

The solution 6 may be heated to a temperature in the first temperature range T1 after the seed crystal 3 has been brought into contact with the solution 6. The solution 6 can dissolve the surface of the seed crystal 3 to remove foreign matter from the surface of the seed crystal 3. As a result, the quality of the crystal 2 grown from the surface of the seed crystal 3 can be improved.

The solution 6 may be heated to a temperature in the first temperature range T1 before the seed crystal 3 is brought into contact with the solution 6. By bringing the seed crystal 3 into contact with the solution 6 after heating the solution 6, the dissolution of the seed crystal 3 can be reduced before the first crystal growth step, and the production efficiency of the crystal 2 can be increased.

(Heating Step)

The solution 6 is heated. For example, if the crystal 2 is doped with nitrogen, this heating can reduce the nitrogen content in the solution 6 because the solubility of nitrogen decreases as the temperature of the solution 6 is increased.

For example, the increase in temperature of the solution 6 may be set in the range of 30° C. to 200° C. If the heating step is performed before the cooling step that will be described later, the solution 6 may be heated to a temperature in a second temperature range T2 higher than the temperatures in the first temperature range T1. For example, the second temperature range T2 may be from 1930° C. to 2300° C. If the heating step is performed after the cooling step that will be described later, the solution 6 may be heated to a temperature in the first temperature range T1. The temperature of the solution 6 can be adjusted by, for example, varying the power of the heating device 11. The heating step may be performed over a period of, for example, 0.5 hour to 3 hours.

The heating step may be performed in a state where the crystal 2 grown in the first growth step is separate from the solution 6. This can reduce the dissolution of the crystal 2, consequently increasing the production efficiency of the crystal 2.

In contrast, the heating step may be performed with the crystal 2 in contact with the solution 6. As a result, the solution 6 can dissolve, for example, the surface of the crystal 2, and even if a groove or the like is formed in the crystal 2, the groove thus can be eliminated.

The crystal 2 may be detached from the solution 6 during the heating step. Thus, the amount of the crystal 2 to be dissolved can be controlled.

The crystal 2 may be detached from the solution 6 while the crystal 2 being rotated. This can reduce the amount of the solution 6 remaining on the lower surface of the crystal 2.

A silicon raw material may be added to the solution 6 in the heating step. Thus, silicon, which is consumed for crystal growth or by evaporation, is supplied. This helps the solution 6 keep the composition thereof as desired. Consequently, the quality of the crystal 2 can be improved.

A silicon raw material may be added before the heating step. Consequently, carbon is sufficiently dissolved in the heating step, and the subsequent second growth step can be started easily.

(Cooling Step)

The solution 6 is cooled. For example, if the crystal 2 is doped with nitrogen, this cooling can increase the nitrogen content in the solution 6 because the solubility of nitrogen increases as the temperature of the solution 6 is reduced.

In the crystal producing method disclosed herein, if the cooling step is performed after the heating step following the first growth step, the nitrogen content in the solution 6 is reduced by the heating step. Hence, if the cooling step is performed without supplying nitrogen, the nitrogen content in the solution 6 is reduced. Thus, a crystal 2 with a reduced nitrogen content can be produced in the second growth step.

If the heating step is performed after the cooling step following the first growth step, as illustrated in FIG. 3, the nitrogen content in the solution 6 is increased by the cooling step. Thus, nitrogen, which is consumed in the first growth step, can be supplied. Thus, a crystal 2 with the same nitrogen content as the crystal 2 grown in the first growth step can be produced in the subsequent second growth step.

By performing the heating step and the cooling step after the first growth step, as described above, the dopant content in the crystal 2 grown in the subsequent second growth step can be adjusted. Also, by adjusting the dopant content as described above, for example, a striped pattern can be formed in the crystal 2. Such a pattern may be used as a mark when the crystal 2 is processed into wafer.

The cooling step may be performed after the heating step. The solution 6 can be thus heated to a temperature in the second temperature range T2. This expands air bubbles formed in the solution 6 during growth. Thus, the air bubbles can be removed from the solution 6 by buoyancy.

The heating step may be performed after the cooling step. Since the highest temperature of the solution 6 is thus in the first temperature range T1, safety measures taken for the apparatus can be reduced, and the capacity of the heater power supply can be reduced. In addition, the power required for production can be reduced. Furthermore, the crystal 2 does not undergo unnecessary temperature history. Consequently, the quality degradation of the crystal 2 can be reduced.

For example, the decrease in temperature of the solution 6 may be set in the range of 30° C. to 200° C. If the cooling step is performed before the heating step, the solution 6 may be heated to a temperature in a third temperature range T3 lower than the temperatures in the first temperature range T1. For example, the third temperature range T3 may be from 1700° C. to 2070° C. If the cooling step is performed after the heating step, the solution 6 may be cooled to a temperature in the first temperature range T1. The cooling step may be performed over a period of, for example, 0.5 hour to 3 hours.

The temperature of the solution 6 may be kept at a temperature equal to or higher than the melting point of silicon, which is the solvent in the solution 6. By keeping the solution 6 at a temperature equal to or higher than the melting point of silicon, the solution 6 can be hindered from expanding in volume, and cracks or breakage of the crucible 5 can be reduced.

The solution 6 may be cooled by keeping the temperature of the lower portion of the solution 6 is lower than the temperature of the upper portion of the solution 6. By cooling the solution 6 in such a manner, the portion of the solution 6 in the vicinity of the bottom of the crucible 5 is cooled. Consequently, impurity crystals are likely to stick to the bottom of the crucible 5.

To cool the lower portion of the solution 6 to a temperature lower than the temperature of the upper portion of the solution 6, the bottom temperature of the crucible 5 may be reduced to a temperature lower than the wall temperature of the crucible 5. The bottom temperature of the crucible 5 can be made lower than the wall temperature of the crucible 5 by locating the crucible 5 below the heating device 11. The temperature of the crucible 5 may be adjusted by reducing the power of the heating device 11 for heating the portion of the crucible 5 in the vicinity of the bottom. Alternatively, the bottom temperature of the crucible 5 may be made lower than the wall temperature of the crucible 5 by moving the heat insulation material 9 between the crucible 5 and the crucible container 8. The temperature of the upper portion of the solution 6 may be reduced by cooling the holding member 4 to increase the quantity of heat transferred from the seed crystal 3 to the holding member 4.

If the heating step is performed after the cooling step, the solution 6 may be heated so that the temperature of the upper portion of the solution 6 becomes higher than the temperature of the lower portion of the solution 6. For example, the solution 6 may be heated so that the wall temperature of the crucible 5 becomes higher than the bottom temperature of the crucible 5. This hinders impurity crystals stuck to the bottom of the crucible 5 from separating from the bottom of the crucible 5 by dissolution of the crucible 5 in the solution 6, and, thus, the impurity crystals taken into the crystal 2 can be reduced.

A silicon raw material may be added in the cooling step. The addition of the silicon raw material, which has a lower temperature than the solution 6, helps cool the solution 6. Thus, the time period of the cooling step can be reduced.

The silicon raw material may be added before the cooling step. A sufficient time thus can be secured to melt the silicon raw material. Consequently, the composition of the solution 6 is stabilized.

In the cooling step, the crystal 2 may be separate from the solution 6 or in contact with the solution 6. If the crystal 2 is separate from the solution 6, the surface of the crystal 2 is hindered from being cooled, and, therefore, the formation of impurity crystals is suppressed at the surface of the crystal 2. Consequently, the quality of the crystal 2 can be improved.

The cooling step and the heating step may be performed for a shorter time than the first and the second growth steps. Consequently, the production efficiency of the crystal 2 can be increased.

The cooling step may be performed for a longer time than the heating step. The occurrence of impurity crystals during cooling can be thus reduced.

The heating step may be performed for a longer time than the cooling step. Temperature can be thus raised at a low power.

(Second Growth Step)

The crystal 2 grown in the first growth step is further grown. The crystal 2 is grown with the solution 6 kept at a temperature in the first temperature range T1. Thus, the crystal 2 is grown under substantially the same conditions as in the first growth step. This helps maintain the quality of the crystal 2. The seed crystal 3 may be pulled at a rate, for example, in the range of 50 μm/h to 2000 μm/h. The temperature of the solution 6 may be set, for example, in the range of 1900° C. to 2100° C. The time period for growing the crystal 2 in the second growth step may be, for example, in the range of 10 hours to 150 hours.

(Removing Step)

After the crystal 2 is grown, the grown crystal 2 is moved from the solution 6 to complete crystal growth.

The present invention is not limited to the embodiments and forms disclosed above, and various modifications and improvements may be made without departing from the spirit and scope of the invention.

In the present invention, the heating and cooling steps and the second growth step may each be repeated a plurality of times. Thus, the crystal 2 can be lengthened.

The order of the heating step and the cooling step may be reversed for each repetition, as illustrated in FIG. 4.

### REFERENCE SIGNS LIST

1 crystal producing apparatus
2 crystal
3 seed crystal
4 holding member
5 crucible
6 Solution
7 moving device
8 crucible container
9 heat insulation material
10 chamber
101 through hole
102 gas supply port
103 exhaust port
11 heating device
12 coil
13 alternating-current power supply
14 controller
T1 first temperature range
T2 second temperature range
T3 third temperature range

1. A method for producing a crystal of silicon carbide, the method comprising:
a preparation step of preparing a seed crystal, a crucible, and a solution in which carbon is dissolved in a silicon solvent in the crucible;
a contact step of bringing a lower surface of the seed crystal into contact with the solution;
a first growth step of heating the solution to a temperature in a first temperature range and pulling the seed crystal upward to grow a crystal from the lower surface of the seed crystal, the temperature of the solution kept in the first temperature range during the first growth step;
a heating step of heating the solution after the first growth step;
a cooling step of cooling the solution after the first growth step; and
a second growth step of further growing the crystal with the temperature of the solution kept in the first temperature range after the heating step and the cooling step.

2. The method according to claim 1, wherein
the cooling step is performed after the heating step,
the solution is heated in the heating step to a temperature in a second temperature range higher than temperatures in the first temperature range, and
the solution is cooled in the cooling step from the temperature in the second temperature range to any temperature in the first temperature range.

3. The method according to claim 1, wherein
the heating step is performed after the cooling step,
the solution is cooled in the cooling step to a temperature in a third temperature range lower than temperatures in the first temperature range, and
the solution is heated in the heating step from the temperature in the third temperature range to any temperature in the first temperature range.

4. The method according to claim 2, wherein
the heating step is performed with the crystal detached from the solution.

5. The method according to claim 2, wherein
the cooling step is performed with the crystal detached from the solution.

6. The method according to claim 2, wherein
the second growth step, the heating step and cooling step are repeated.

7. The method according to claim 2, wherein
the solution is cooled in the cooling step by keeping a temperature of a lower portion of the solution lower than a temperature of an upper portion of the solution as the solution cools.

8. The method according to claim 3, wherein
temperatures in the third temperature range are equal to or higher than a melting point of silicon.

9. The method according to claim 3, wherein
the heating step is performed with the crystal detached from the solution.

10. The method according to claim 3, wherein
the cooling step is performed with the crystal detached from the solution.

11. The method according to claim 4, wherein
the cooling step is performed with the crystal detached from the solution.

12. The method according to claim 3, wherein
the second growth step, the heating step and the cooling step are repeated.

13. The method according to claim 4, wherein
the second growth step, the heating step and the cooling step are repeated.

14. The method according to claim 5, wherein
the second growth step, the heating step the and cooling step are repeated.

15. The method according to claim 3, wherein
the solution is cooled in the cooling step by keeping a temperature of the lower portion of the solution lower than a temperature of an upper portion of the solution as the solution cools.

16. The method according to claim 4, wherein
the solution is cooled in the cooling step by keeping a temperature of the lower portion of the solution lower than a temperature of an upper portion of the solution as the solution cools.

17. The method according to claim 5, wherein
the solution is cooled in the cooling step by keeping a temperature of the lower portion of the solution lower than a temperature of an upper portion of the solution as the solution cools.

18. The method according to claim 6, wherein
the solution is cooled in the cooling step by keeping a temperature of the lower portion of the solution than a temperature of an upper portion of the solution as the solution cools.
